(19) United States
(12) Patent Application Publication
(10) Pub. No.: US 2010/0271785 A1
(43) Pub. Date: Oct. 28, 2010

(54) HEAT-DISSIPATING AND FIXING MECHANISM OF ELECTRONIC COMPONENT AND PROCESS FOR ASSEMBLING SAME

(76) Inventors: Hung-Chang Hsieh, Taoyuan Hsien (TW); Chi-Sheng Chen, Taoyuan Hsien (TW); Ren-Shen Huang, Taoyuan Hsien (TW)

Correspondence Address: AUSTIN RAPP & HARDMAN, 170 South Main Street, Suite 735, SALT LAKE CITY, UT, 84101, US

(21) Appl. No.: 12/489,120

(22) Filed: Jun. 22, 2009

(30) Foreign Application Priority Data
Apr. 22, 2009 (TW) 098113376

(51) Int. Cl. H05K 7/20; H05K 13/04

(52) U.S. Cl. 361/717; 361/720; 29/739; 361/719

(57) ABSTRACT

A heat-dissipating and fixing mechanism of an electronic component includes a heat-dissipating element, a circuit board and a thermally-conductive adhesive interface. The circuit board has multiple insertion holes. The pins of the electronic component are inserted into corresponding insertion holes of the circuit board. The thermally-conductive adhesive interface has a first surface bonded with the heat-dissipating element and a second surface bonded with the electronic component. As a consequence, the electronic component is fixed on the heat-dissipating element through the thermally-conductive adhesive interface, and the heat generated by the electronic component is transmitted to the heat-dissipating element through the thermally-conductive adhesive interface.

### CLAIM OF PRIORITY

This application claims priority to Taiwanese Patent Application No. 098113376 filed on Apr. 22, 2009.

### FIELD OF THE INVENTION

The present invention relates to a heat-dissipating and fixing mechanism, and more particularly to a heat-dissipating and fixing mechanism of an electronic component. The present invention also relates to a process for assembling a heat-dissipating and fixing mechanism.

### BACKGROUND OF THE INVENTION

With the rapid progress of semiconductor industries, the integrated circuits (ICs) used in electronic devices are developed toward minimization, high operating speed and increasing integration level. Due to the reduced size and the increased performance, power semiconductor devices such as power transistors have achieved a great deal of advance. The power transistors are used in many electronic devices such as control equipment, measuring equipment, electrical apparatuses and computer peripheral devices because they are very suitable to process high-power signals. During operation of the electronic device, the power transistors may generate energy in the form of heat, which is readily accumulated and difficult to dissipate away. If no proper heat-dissipating mechanism is provided to transfer enough heat to the ambient air, the elevated operating temperature may result in damage of the electronic components, a breakdown of the whole electronic device or reduced operation efficiency. Therefore, it is important to dissipate the heat generated from the power transistors in order to stabilize the operation and extend the operational life of the electronic device.

Typically, the power transistors are fastened onto a surface of a heat sink in order to increase the heat-dissipating efficiency. FIG. 1 is a schematic exploded view illustrating a power transistor to be fastened onto a heat sink. FIG. 2 is a schematic cross-sectional view illustrating the assembled structure of the power transistor and the heat sink. By means of a screw 11, a washer 15 and a nut 16, a power transistor 13 is fastened onto a heat sink 14. By means of a plastic bushing 12, the power transistor 13 is separated from the screw 11 and the heat sink 14 in order to prevent spark generation and short-circuit breakdown.

The conventional process for fastening the power transistor 13 onto the heat sink 14 is usually labor-intensive. That is, after the screw 11 is sheathed by the plastic bushing 12, the combination of the screw 11 and the plastic bushing 12 is successively penetrated through the perforation 132 of the insulating package structure 131 of the power transistor 13 and the through-hole 141 of the heat sink 14. As such, the screw 11 is partially protruded outside the backside of the heat sink 14. After the screw 11 is engaged with the washer 15 and the nut 16, the power transistor 13 is firmly fastened onto the heat sink 14. Since the electronic components are developed toward minimization, the size of the power transistor 13 is gradually reduced. Under this circumstance, the process for fastening the power transistor becomes more complicated and difficult.

Furthermore, after the power transistor 13 is fastened onto the heat sink 14, the pins 133 of the power transistor 13 are inserted into corresponding insertion holes of a circuit board (not shown). In a case that the power transistor 13 is inclined with respect to the heat sink 14 after the screw 11 is engaged with the washer 15 and the nut 16, the pins 133 of the power transistor 13 fail to be precisely aligned with corresponding insertion holes of the circuit board. As such, the power transistor 13 fails to be mounted on the circuit board.

Since electronic devices are developed toward minimization, high-density mounting is needed. After the power transistor 13 is fastened onto the heat sink 14, the head portion 111 of the screw 11 is not covered by the plastic bushing 12 and exposed outsides (see FIG. 2). If the electronic device is suffered from a drop or a strong impact, the head portion 111 of the screw 11 is possibly in contact with adjacent electronic components. In this circumstance, the electronic device will be short-circuited or even damaged.

For solving the above problems, an insulating piece is manually placed in the vicinity of the screw 11 to isolate the screw 11 from other electronic components. Since the insulating piece is not suitably positioned, the insulating piece is readily detached from the original position if the electronic device is suffered from a drop or a strong impact. That is, the head portion 111 of the screw 11 may be still in contact with adjacent electronic components. In addition, manually positioning the insulating piece is labor-intensive and time-consuming.

Therefore, there is a need of providing a heat-dissipating and fixing mechanism of an electronic component so as to obviate the drawbacks encountered from the prior art.

### SUMMARY OF THE INVENTION

It is an object of the present invention to provide a heat-dissipating and fixing mechanism of an electronic component in order to remove the heat generated from the electronic component and facilitate securely fixing the electronic component on a circuit board.

In accordance with an aspect of the present invention, there is provided a heat-dissipating and fixing mechanism of an electronic component. The electronic component has multiple pins. The heat-dissipating and fixing mechanism includes a heat-dissipating element, a circuit board and a thermally-conductive adhesive interface. The circuit board has multiple insertion holes. The pins of the electronic component are inserted into corresponding insertion holes of the circuit board. The thermally-conductive adhesive interface has a first surface bonded with the heat-dissipating element and a second surface bonded with the electronic component. As a consequence, the electronic component is fixed on the heat-dissipating element through the thermally-conductive adhesive interface, and the heat generated by the electronic component is transmitted to the heat-dissipating element through the thermally-conductive adhesive interface.

In accordance with another aspect of the present invention, there is provided a process for assembling a heat-dissipating and fixing mechanism. Firstly, a heat-dissipating element is provided. Then, a first surface of a thermally-conductive adhesive interface is attached on the heat-dissipating element. Then, an electronic component is attached on a second surface of the thermally-conductive adhesive interface, wherein the electronic component has multiple pins. Afterwards, a circuit board having multiple insertion holes is provided, and the pins of the electronic component are inserted into corresponding insertion holes of the circuit board.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic exploded view illustrating a power transistor to be fastened onto a heat sink;

FIG. 2 is a schematic cross-sectional view illustrating the assembled structure of the power transistor and the heat sink;

FIG. 3 is a schematic exploded view illustrating a heat-dissipating and fixing mechanism of an electronic component according to an embodiment of the present invention;

FIG. 4A is a schematic perspective view illustrating the heat-dissipating and fixing mechanism of the electronic component to be mounted on a circuit board;

FIG. 4B is a schematic cross-sectional view illustrating the heat-dissipating and fixing mechanism of the electronic component that has been mounted on the circuit board;

FIG. 5A is a schematic cross-sectional view illustrating an exemplary thermally-conductive adhesive interface used in the heat-dissipating and fixing mechanism of the present invention;

FIG. 5B is a schematic cross-sectional view illustrating another exemplary thermally-conductive adhesive interface used in the heat-dissipating and fixing mechanism of the present invention; and

FIG. 6 is a flowchart schematically illustrating a process for assembling a heat-dissipating and fixing mechanism according to the present invention.

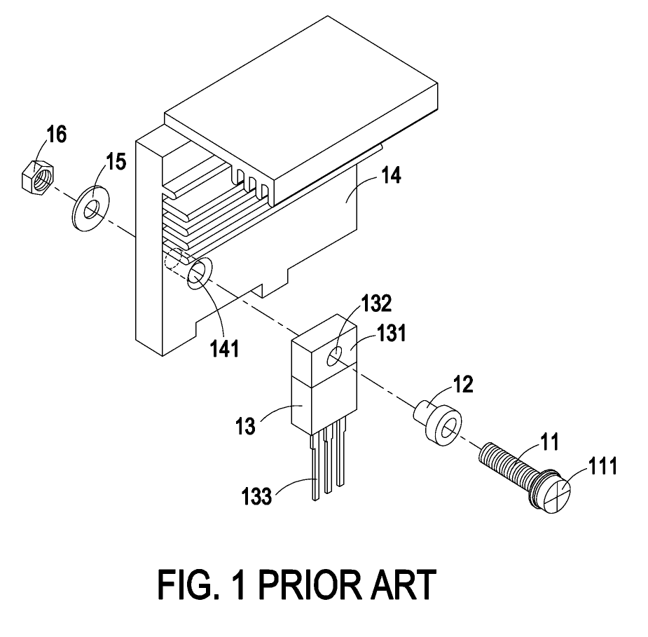

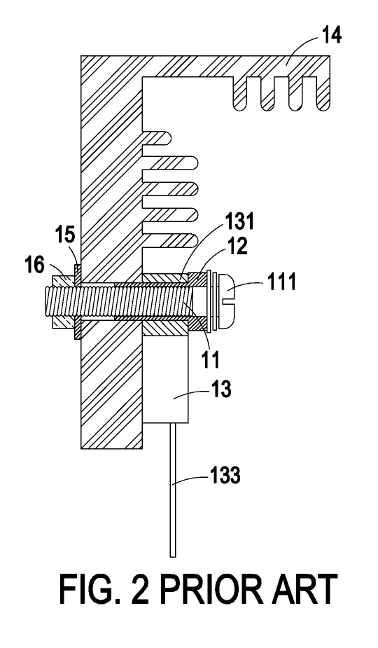

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

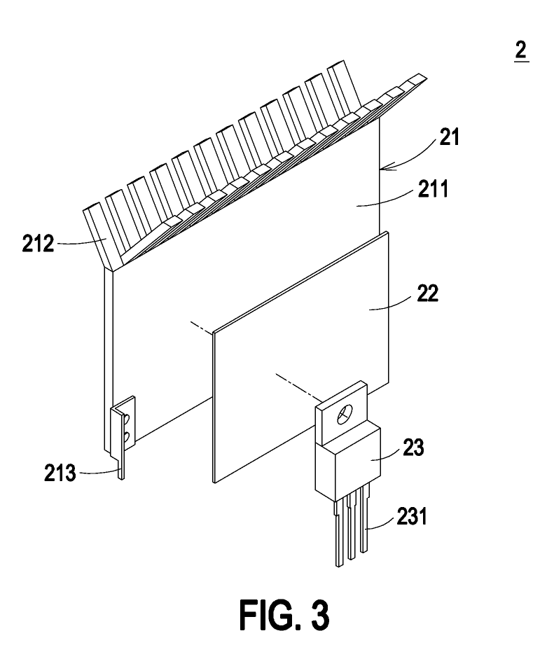

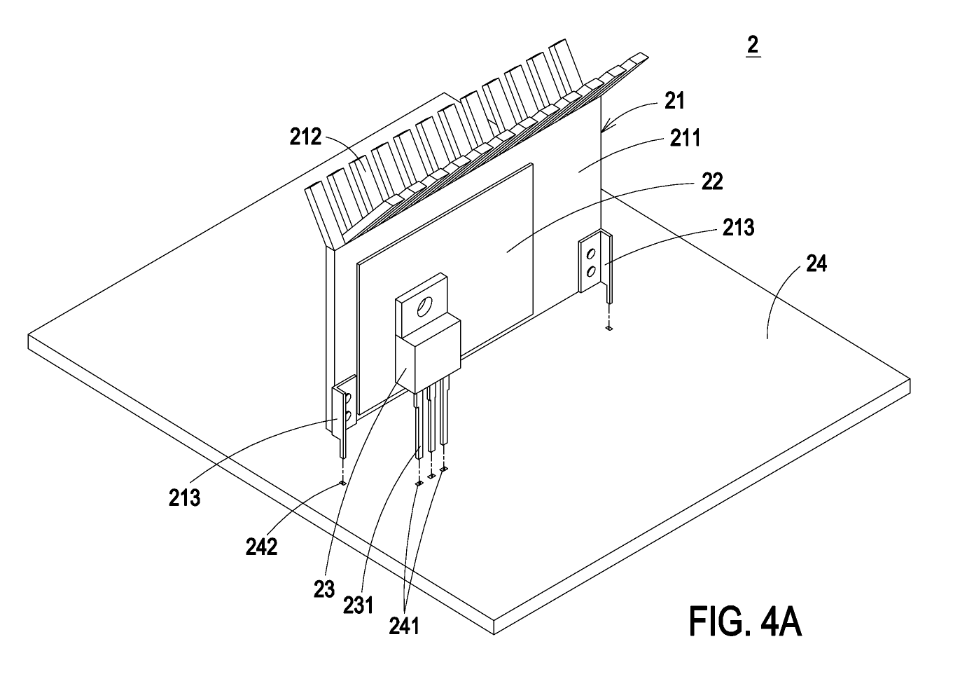

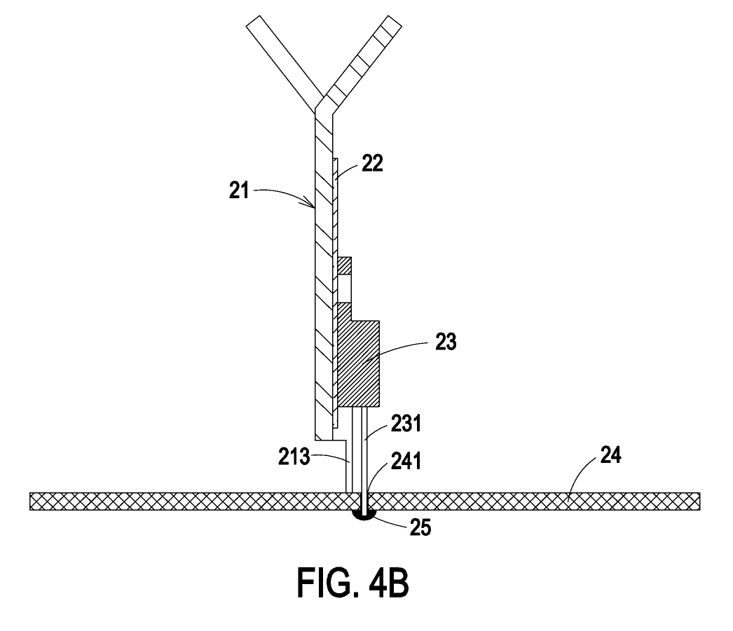

FIG. 3 is a schematic exploded view illustrating a heat-dissipating and fixing mechanism of an electronic component according to an embodiment of the present invention. FIG. 4A is a schematic perspective view illustrating the heat-dissipating and fixing mechanism of the electronic component to be mounted on a circuit board. FIG. 4B is a schematic cross-sectional view illustrating the heat-dissipating and fixing mechanism of the electronic component that has been mounted on the circuit board. Please refer to FIGS. 3, 4A and 4B. The heat-dissipating and fixing mechanism 2 comprises a heat-dissipating element 21, a thermally-conductive adhesive interface 22 and a circuit board 24. The heat-dissipating and fixing mechanism 2 is used to remove the heat generated from an electronic component 23 and facilitate securely fixing the electronic component 23 on the circuit board 24. An example of the electronic component 23 includes but is not limited to a solid-state electronic component, for example a power transistor. The electronic component 23 has multiple pins 231. The circuit board 24 has multiple insertion holes 241 corresponding to the pins 231. The thermally-conductive adhesive interface 22 is arranged between the heat-dissipating element 21 and the electronic component 23. The thermally-conductive adhesive interface 22 has a first surface bonded with the heat-dissipating element 21 and a second surface bonded with the electronic component 23. As such, the electronic component 23 can be fixed on the heat-dissipating element 21 via the thermally-conductive adhesive interface 22 (see FIG. 4A). Furthermore, the heat generated by the electronic component 23 could be transmitted to the heat-dissipating element 21 through the thermally-conductive adhesive interface 22. After the electronic component 23 is fixed on the heat-dissipating element 21 via the thermally-conductive adhesive interface 22, the pins 231 of the electronic component 23 are inserted into corresponding insertion holes 241 of the circuit board 24.

Examples of the insertion holes 241 are conductive holes. After the pins 231 of the electronic component 23 are inserted into corresponding insertion holes 241 of the circuit board 24, solder paste 25 is coated on the junctions between the pins 231 and the insertion holes 241. Then, the combination of the heat-dissipating element 21, the thermally-conductive adhesive interface 22 and the electronic component 23 as well as the circuit board 24 are heated in a reflow furnace to melt the solder paste 25. Afterwards, the circuit board 24 is cooled to solidify the solder paste 25, so that the electronic component 23 is further fixed on and electrically connected to the circuit board 24 (see FIG. 4).

Please refer to FIG. 3 again. An example of the heat-dissipating element 21 includes but is not limited to a heat sink. In some embodiments, the heat-dissipating element 21 is perpendicular to the circuit board 24. For increasing the heat-dissipating efficiency of the heat-dissipating element 21, multiple staggered fins 212 are extended from the top surface of the main body 211 of the heat-dissipating element 21. In some embodiments, two inserting parts 213 are disposed on the bilateral sides of the main body 211 of the heat-dissipating element 21. In addition, the circuit board 24 has through-holes 242 corresponding to the inserting parts 213. After the inserting parts 213 are inserted into corresponding through-holes 242 of the circuit board 24, the heat-dissipating element 21 is further fixed on the circuit board 24.

Please refer to FIG. 3 again. The thermally-conductive adhesive interface 22 has thermally conductive, heat-resistant, electrically isolative and adherent properties. Due to the adherent property, the electronic component 23 can be fixed on the heat-dissipating element 21 via the thermally-conductive adhesive interface 22. Due to the thermally conductive, heat-resistant and electrically isolative properties, the heat generated by the electronic component 23 can be effectively transmitted to the heat-dissipating element 21 through the thermally-conductive adhesive interface 22. It is preferred that the thermally-conductive adhesive interface 22 can withstand a high temperature above 150° C. (e.g. from 150° C. to 300° C.). Moreover, by means of the thermally-conductive adhesive interface 22, the electronic component 23 is separated from the heat-dissipating element 21 in order to prevent spark generation and short-circuit breakdown.

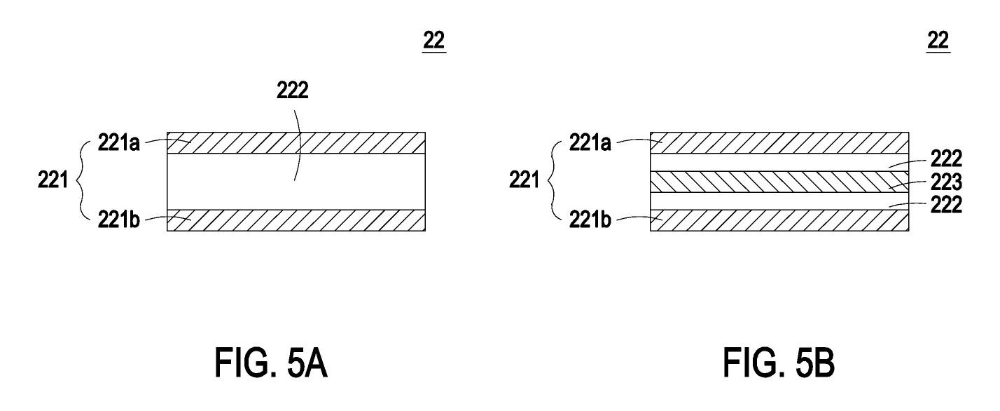

FIG. 5A is a schematic cross-sectional view illustrating an exemplary thermally-conductive adhesive interface used in the heat-dissipating and fixing mechanism of the present invention. In this embodiment, the thermally-conductive adhesive interface 22 is a double-faced adhesive tape, which has a first surface bonded with the heat-dissipating element 21 and a second surface bonded with the electronic component 23. As shown in FIG. 5A, the thermally-conductive adhesive interface 22 comprises a first adhesive layer 221a, a second adhesive layer 221b and a thermally-conductive layer 222. The thermally-conductive layer 222 is arranged between the first adhesive layer 221a and the second adhesive layer 221b. In other words, the first adhesive layer 221a and the second adhesive layer 221b are disposed on opposite surfaces of the thermally-conductive adhesive interface 22. The first adhesive layer 221a and the second adhesive layer 221b are bonded with the heat-dissipating element 21 and the electronic component 23, respectively. Moreover, the heat generated by the electronic component 23 could be transmitted to the heat-dissipating element 21 through the thermally-conductive layer 222 of the thermally-conductive adhesive interface 22.

FIG. 5B is a schematic cross-sectional view illustrating another exemplary thermally-conductive adhesive interface used in the heat-dissipating and fixing mechanism of the present invention. In this embodiment, the thermally-conductive adhesive interface 22 comprises a first adhesive layer 221a, a second adhesive layer 221b, two thermally-conductive layers 222 and a metallic layer 223. The metallic layer 223 is arranged between the adhesive layers 221 and contacted with at least one of the thermally-conductive layers 222. The arrangement of the metallic layer 223 can enhance the heat-dissipating efficiency of the thermally-conductive adhesive interface 22.

In some embodiments, the thermally-conductive adhesive interface 22 is a liquid gluing agent, which is made of thermosetting plastic material. After the thermally-conductive adhesive interface 22 is applied on a surface of the heat-dissipating element 21 by an automatic machine, the electronic component 23 could be attached on the heat-dissipating element 21 via the thermally-conductive adhesive interface 22.

In some embodiments, the thermally-conductive adhesive interface 22 is made of polyimide, polyester, polyimide, aluminum, aluminum hydroxide, boron nitride or the combination thereof.

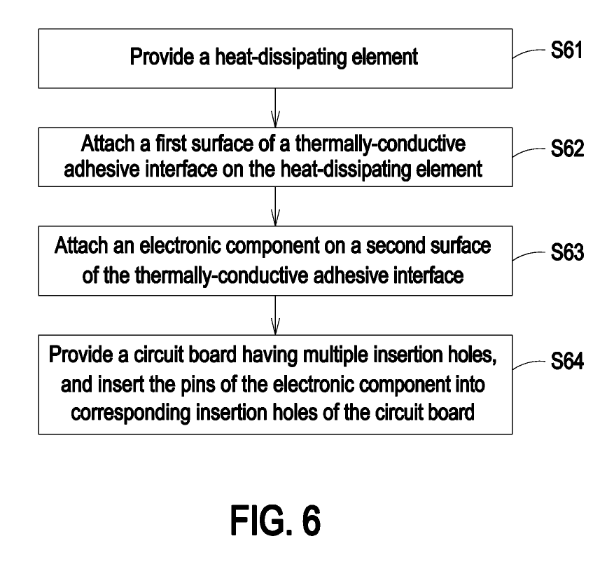

FIG. 6 is a flowchart schematically illustrating a process for assembling a heat-dissipating and fixing mechanism according to the present invention. Hereinafter, the process for assembling the heat-dissipating and fixing mechanism will be illustrated in more details with reference to FIGS. 3, 4 and 6. First of all, a heat-dissipating element 21 is provided (Step S61). Next, a first surface of the thermally-conductive adhesive interface 22 is attached on the heat-dissipating element 21 by an automatic machine (Step S62). Next, the electronic component 23 is attached on a second surface of the thermally-conductive adhesive interface 22 by the automatic machine (Step S63). Afterwards, a circuit board 24 having multiple insertion holes 241 is provided, and the pins 231 of the electronic component 23 are inserted into corresponding insertion holes 241 of the circuit board 24 (Step S64). Meanwhile, the electronic component 23 is attached on the heat-dissipating element 21, and the heat-dissipating element 21 and the electronic component 23 are fixed on the circuit board 24.

From the above embodiment, the heat-dissipating and fixing mechanism of the present invention is effective to remove the heat generated from the electronic component and facilitate securely fixing the electronic component on a circuit board. Due to the adherent property of the thermally-conductive adhesive interface, the electronic component can be fixed on the heat-dissipating element. Due to the thermally conductive, heat-resistant and electrically isolative properties of the thermally-conductive adhesive interface, the heat generated by the electronic component can be effectively transmitted to the heat-dissipating element through the thermally-conductive adhesive interface. Since the electronic component is firmly fixed on the heat-dissipating element, the pins of the electronic component could be precisely aligned with corresponding insertion holes of the circuit board. In addition, since no screw is needed, the problem of erroneously contacting the head portion of the screw with adjacent electronic components will be overcome. Since the process for assembling the heat-dissipating and fixing mechanism of the present invention can be automatically implemented, the fabricating process is simplified and cost-effective.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat-dissipating and fixing mechanism of an electronic component, said electronic component having multiple pins, said heat-dissipating and fixing mechanism comprising:
a heat-dissipating element;
a circuit board having multiple insertion holes, wherein said pins of said electronic component are inserted into corresponding insertion holes of said circuit board; and
a thermally-conductive adhesive interface having a first surface bonded with said heat-dissipating element and a second surface bonded with said electronic component, so that said electronic component is fixed on said heat-dissipating element through said thermally-conductive adhesive interface, and the heat generated by said electronic component is transmitted to said heat-dissipating element through said thermally-conductive adhesive interface.

2. The heat-dissipating and fixing mechanism according to claim 1 wherein said heat-dissipating element is perpendicular to said circuit board.

3. The heat-dissipating and fixing mechanism according to claim 1 wherein said electronic component is a solid-state electronic component.

4. The heat-dissipating and fixing mechanism according to claim 3 wherein said electronic component is a power transistor.

5. The heat-dissipating and fixing mechanism according to claim 1 wherein said thermally-conductive adhesive interface is a double-faced adhesive tape.

6. The heat-dissipating and fixing mechanism according to claim 5 wherein said thermally-conductive adhesive interface comprises multiple adhesive layers and at least one thermally-conductive layer, wherein said at least one thermally-conductive layer is arranged between said adhesive layers, and said adhesive layers are respectively bonded with said heat-dissipating element and said electronic component.

7. The heat-dissipating and fixing mechanism according to claim 6 wherein said thermally-conductive adhesive interface comprises a first adhesive layer, a second adhesive layer and a thermally-conductive layer, and said first adhesive layer and said second adhesive layer are disposed on opposite surfaces of said thermally-conductive adhesive interface to be respectively bonded with said heat-dissipating element and said electronic component.

8. The heat-dissipating and fixing mechanism according to claim 6 wherein said thermally-conductive adhesive interface further comprises at least a metallic layer, which is arranged between said adhesive layers and in contact with said at least one thermally-conductive layer.

9. The heat-dissipating and fixing mechanism according to claim 8 wherein said thermally-conductive adhesive interface is made of polyimide, polyester, polyimide, aluminum, aluminum hydroxide, boron nitride or the combination thereof.

10. The heat-dissipating and fixing mechanism according to claim 1 wherein said thermally-conductive adhesive interface is a liquid gluing agent.

11. The heat-dissipating and fixing mechanism according to claim 10 wherein said liquid gluing agent is made of thermosetting plastic material.

12. The heat-dissipating and fixing mechanism according to claim 1 wherein said thermally-conductive adhesive interface is permitted to withstand a high temperature above 150° C.

13. The heat-dissipating and fixing mechanism according to claim 12 wherein said thermally-conductive adhesive interface is permitted to withstand a high temperature from 150° C. to 300° C.

14. The heat-dissipating and fixing mechanism according to claim 1 wherein said heat-dissipating element is further fixed on said circuit board.

15. A process for assembling a heat-dissipating and fixing mechanism, said process comprising steps of:
providing a heat-dissipating element;
attaching a first surface of a thermally-conductive adhesive interface on said heat-dissipating element;
attaching an electronic component on a second surface of said thermally-conductive adhesive interface, wherein said electronic component has multiple pins; and
providing a circuit board having multiple insertion holes, and inserting said pins of said electronic component into corresponding insertion holes of said circuit board.
